(19) United States
(12) Patent Application Publication
(10) Pub. No.: US 2024/0260323 A1
(43) Pub. Date: Aug. 1, 2024

(54) LIGHT EMITTING DISPLAY DEVICE AND METHOD OF MANUFACTURING SAME

(71) Applicant: LG DISPLAY CO., LTD., SEOUL (KR)

(72) Inventors: Soo Won HWANG, Paju-si (KR); Seong Ho OH, Paju-si (KR)

(73) Assignee: LG DISPLAY CO., LTD., SEOUL (KR)

(21) Appl. No.: 18/388,910

(22) Filed: Nov. 13, 2023

(30) Foreign Application Priority Data
Jan. 30, 2023 (KR) 10-2023-0011784

(51) Int. Cl. H10K 59/122; H10K 59/12

(52) U.S. Cl. CPC H10K 59/122; H10K 59/1201

(57) ABSTRACT

A light emitting display device includes a plurality of anodes spaced apart from each other on a substrate, an auxiliary electrode between adjacent anodes among the plurality of anodes, a bank exposing light emitting parts of the plurality of anodes and having a bank hole exposing a part of the auxiliary electrode, a bank protection pattern on a bank side surface surrounding the bank hole and on the bank around the bank hole, an interlayer on the light emitting parts and the bank, and a cathode connected to the auxiliary electrode within the bank hole. A connection portion between the auxiliary electrode and the cathode is provided in an active area to apply a uniform voltage to the entire display area and prevent luminance non-uniformity. By the bank protection pattern, the interlayer is prevented from being damaged due to outgassing from an exposure of the bank.

### CROSS-REFERENCE TO RELATED APPLICATION

This application claims the priority of Korean Patent Application No. 10-2023-0011784, filed on Jan. 30, 2023, which is hereby incorporated by reference in its entirety.

### BACKGROUND

### Field of the Disclosure

The present disclosure relates to a display device, and more particularly, to a light emitting display device capable of preventing outgassing by preventing exposure of a bank structure around an auxiliary electrode and a method of manufacturing the same.

### Description of the Background

With the development of the information society, demand for display devices for displaying images in various forms is increasing.

A light emitting display device in which pixels are composed of light emitting elements does not require a separate light source and thus is advantageous in implementation of a slim and flexible structure and has a high color purity.

For example, a light emitting element includes two different electrodes and an emission layer interposed therebetween. When electrons generated from one electrode and holes generated from the other electrode are injected into the emission layer, the injected electrons and holes are recombined, thus generating excitons, and light emission occurs as the generated excitons fall from an excited state to a ground state.

In such a light emitting display device, the light emitting element included in a pixel has one of two opposing electrodes in the form of a common electrode which is common to all pixels. As the area of the display device increases, luminance non-uniformity may occur due to resistance differences in regions in the common electrode caused by distance differences from a power supply.

Further, as the thickness of the common electrode decreases for transparency, the resistance of the common electrode increases, causing voltage drop, and thus the current of the light emitting element may vary or decrease.

### SUMMARY

Accordingly, the present disclosure is directed to a light emitting display device and a method of manufacturing the same that substantially obviate one or more problems due to limitations and disadvantages described above.

More specifically, the present disclosure is to provide a light emitting display device including a connection portion of an auxiliary electrode and a cathode in an active area such that a uniform voltage may be applied to the entire display area through the cathode, to prevent luminance non-uniformity.

In addition, the light emitting display device of the present disclosure is formed in such a manner that the auxiliary electrode partially overlaps with a bank, and a bank protection pattern is provided around a bank hole to prevent damage to an interlayer due to outgassing in an exposed portion of the bank, thereby improving the reliability of the light emitting display device.

Additional advantages and features of the disclosure will be set forth in part in the description which follows and in part will become apparent to those having ordinary skill in the art upon examination of the following or may be learned from practice of the disclosure. Other advantages of the disclosure may be realized and attained by the structure particularly pointed out in the written description and claims hereof as well as the appended drawings.

To achieve these and other advantages and in accordance with the present disclosure, as embodied and broadly described herein, a light emitting display device includes a plurality of anodes spaced apart from each other on a substrate, an auxiliary electrode between adjacent anodes among the plurality of anodes, a bank exposing light emitting parts of the plurality of anodes and having a bank hole exposing a part of the auxiliary electrode, a bank protection pattern on a bank side surface surrounding the bank hole and on the bank around the bank hole, an interlayer on the light emitting parts and the bank, and a cathode connected to the auxiliary electrode within the bank hole.

In another aspect of the present disclosure, a method of manufacturing a light emitting display device includes a first step of forming a plurality of anodes spaced apart from each other on a substrate; a second step of forming an auxiliary electrode between adjacent anodes among the plurality of anodes; a third step of forming a bank exposing light emitting parts of the plurality of anodes; a fourth step of forming a first protection pattern on the bank; and a fifth step of forming an interlayer and a cathode overlapping with the first protection pattern.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the present disclosure, illustrate aspects of the disclosure and together with the description serve to explain the principle of the disclosure.

In the drawings:

FIG. 1 is a schematic block diagram of a light emitting display device according to the present disclosure;

FIG. 2 is a cross-sectional view illustrating a light emitting display device according to an aspect of the present disclosure;

FIG. 3 is a plan view illustrating a light emitting display device according to a first aspect of the present disclosure;

FIG. 4 is a plan view illustrating a light emitting display device according to a second aspect of the present disclosure; and

FIGS. 5A to 5E are cross-sectional views illustrating a process of a method of manufacturing the light emitting display device according to the present disclosure.

### DETAILED DESCRIPTION

Reference will now be made in detail to the various aspects of the present disclosure, examples of which are illustrated in the accompanying drawings. Wherever possible, the same reference numbers will be used throughout the drawings to refer to the same or like parts. In the following description of the present disclosure, detailed descriptions of known functions and configurations incorporated herein will be omitted when the same may obscure the subject matter of the present disclosure. In addition, the names of elements used in the following description are selected in consideration of clear description of the specification, and may differ from the names of elements of actual products.

The shape, size, ratio, angle, number, and the like shown in the drawings to illustrate various aspects of the present disclosure are merely provided for illustration, and are not limited to the content shown in the drawings. Wherever possible, the same reference numbers will be used throughout the drawings to refer to the same or like parts. In the following description, detailed descriptions of technologies or configurations related to the present disclosure may be omitted to avoid unnecessarily obscuring the subject matter of the present disclosure. When terms such as “including”, “having”, and “comprising” are used throughout the specification, an additional component may be present, unless “only” is used. A component described in a singular form encompasses a plurality thereof unless particularly stated otherwise.

The components included in the aspects of the present disclosure should be interpreted to include an error range, even if there is no additional particular description thereof.

In describing a variety of aspects of the present disclosure, when terms for positional relationships such as “on”, “above”, “under” and “next to” are used, at least one intervening element may be present between two elements, unless “immediately” or “directly” is used.

In describing a variety of aspects of the present disclosure, when terms related to temporal relationships, such as “after”, “subsequently”, “next” and “before”, are used, the non-continuous case may be included, unless “immediately” or “directly” is used.

In describing a variety of aspects of the present disclosure, terms such as “first” and “second” may be used to describe a variety of components, but these terms only aim to distinguish the same or similar components from one another. Accordingly, throughout the specification, a “first” component may be the same as a “second” component within the technical concept of the present disclosure, unless specifically mentioned otherwise.

Features of various aspects of the present disclosure may be partially or completely coupled to or combined with each other, and may be variously inter-operated with each other and driven technically. The aspects of the present disclosure may be carried out independently from each other, or may be carried out together in an interrelated manner.

Hereinafter, a light emitting display device and a method of manufacturing the same according to the present disclosure will be described with reference to the drawings.

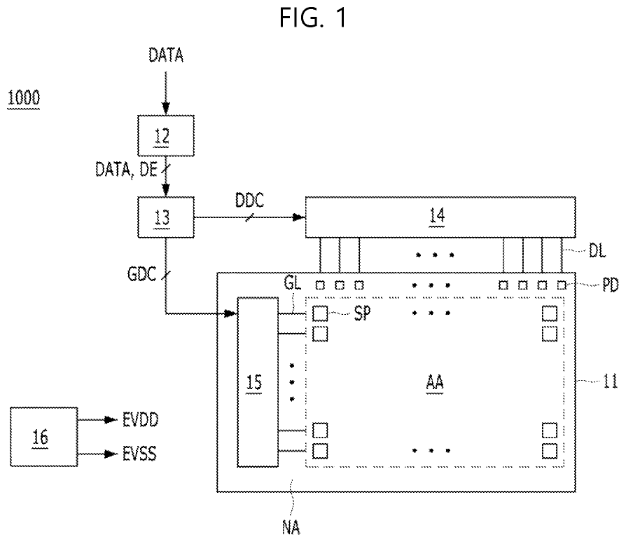

FIG. 1 is a schematic block diagram of a light emitting display device according to an aspect of the present disclosure.

As illustrated in FIG. 1, the light emitting display device 1000 according to an aspect of the present disclosure may include a display panel 11, an image processor 12, a timing controller 13, a data driver 14, a scan driver 15, and a power supply 16.

The display panel 11 may display an image in response to a data signal DATA supplied from the data driver 14, a scan signal supplied from the scan driver 15, and power supplied from the power supply 16.

The display panel 11 may include sub-pixels SP disposed at intersections of a plurality of gate lines GL and a plurality of data lines DL. The structure of the sub-pixel SP may be changed in various manners depending on the type of the light emitting display device 1000.

For example, the sub-pixels SP may be formed in a top emission structure, a bottom emission structure, or a dual emission structure. The sub-pixels SP refer to units capable of emitting lights of respective colors with or without a specific type of color filter. For example, the sub-pixels SP may include a red sub-pixel, a green sub-pixel, and a blue sub-pixel. Alternatively, the sub-pixels SP may include, for example, a red sub-pixel, a blue sub-pixel, a white sub-pixel, and a green sub-pixel. The sub-pixels SP may have one or more different emission areas according to light emitting characteristics. For example, a blue sub-pixel and sub-pixels emitting lights of different colors may have different emission areas.

One or more sub-pixels SP may constitute one unit pixel. For example, one unit pixel may include red, green, and blue sub-pixels, and the red, green, and blue sub-pixels may be repeatedly disposed. Alternatively, one unit pixel may include red, green, blue, and white sub-pixels, and the red, green, blue, and white sub-pixels may be repeatedly arranged or may be disposed in a quad type. In an aspect according to the present disclosure, the sub-pixels may have various color types, arrangement types, and arrangement orders according to light emitting characteristics, device lifespan, and device specifications, but the present disclosure is not limited thereto.

The display panel 11 may be divided into a display area AA (area defined by a dotted line) in which sub-pixels SP are disposed to display an image, and a non-display area NA around the display area AA. The scan driver 15 may be provided in the non-display area NA of the display panel 11. In addition, the non-display area NA may include a pad portion PAD including pad electrodes PD.

Here, the display area AA may also be referred to as an active area, and the non-display area NA may also be referred to as a non-active area.

The image processor 12 may output a data enable signal DE along with an externally supplied data signal DATA. The image processor 12 may output one or more of a vertical synchronization signal, a horizontal synchronization signal, and a clock signal in addition to the data enable signal DE, but illustration of these signals is omitted for convenience of description.

The timing controller 13 may receive the data signal DATA along with driving signals from the image processor 12. The driving signals may include the data enable signal DE. Alternatively, the driving signals may include the vertical synchronization signal, the horizontal synchronization signal, and the clock signal. The timing controller 13 may output a data timing control signal DDC for controlling operation timing of the data driver 14 and a gate timing control signal GDC for controlling operation timing of the scan driver 15 on the basis of the driving signals.

The data driver 14 may sample and latch the data signal DATA supplied from the timing controller 13 in response to the data timing control signal DDC supplied from the timing controller 13, convert the same into a gamma reference voltage, and outputs the gamma reference voltage.

The data driver 14 may output the data signal DATA through the data lines DL. The data driver 14 may be implemented in the form of an integrated circuit (IC). For example, the data driver 14 may be electrically connected to the pad electrodes PD disposed in the non-display area NA of the display panel 11 through a flexible circuit film (not shown).

The scan driver 15 may output a scan signal in response to the gate timing control signal GDC supplied from the timing controller 13. The scan driver 15 may output the scan signal through the gate lines GL. The scan driver 15 may be implemented in the form of an integrated circuit (IC) or implemented in the display panel 11 in a gate-in-panel (GIP) structure.

The power supply 16 may output a high-potential voltage and a low-potential voltage for driving the display panel 11. The power supply 16 may supply the high-potential voltage to the display panel 11 through a first power line EVDD (driving power line or pixel power line), and may supply the low-potential voltage to the display panel 11 through a second power line EVSS (auxiliary power line or common power line).

The display panel 11 is divided into the display area AA and the non-display area NA, and may include a plurality of sub-pixels SP defined by gate lines GL and data lines DL intersecting each other in a matrix form in the display area AA.

The sub-pixels SP may include sub-pixels emitting at least two of red light, green light, blue light, yellow light, magenta light, and cyan light. In addition, the plurality of sub-pixels SP may emit respective colors with or without a specific type of color filter. However, the present disclosure is not necessarily limited thereto, and the sub-pixels SP may have various color types, arrangement types, and arrangement orders according to light emitting characteristics, device lifespan, and device specifications, etc.

Each of the sub-pixels SP may include a light emitting part through which light is emitted and a non-emitting part around the light emitting part.

Hereinafter, configurations of the light emitting part and the non-light emitting part of the display area will be described with reference to the drawings.

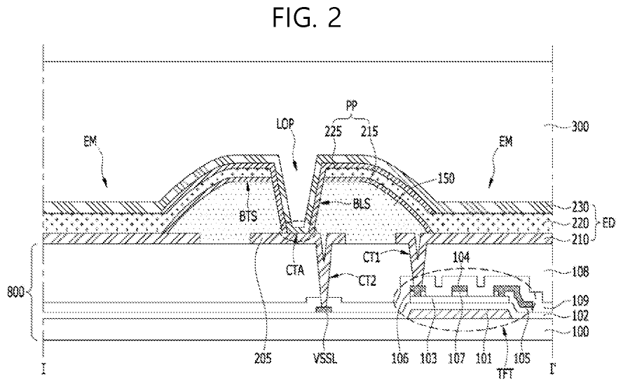

FIG. 2 is a cross-sectional view illustrating a light emitting display device according to an aspect of the present disclosure.

As illustrated in FIG. 2, the light emitting display device according to a first aspect of the present disclosure includes a plurality of anodes 210 spaced apart from each other on a substrate 100, an auxiliary electrode 205 positioned between adjacent anodes among the plurality of anodes, a bank 150 having a bank hole LOP exposing light emitting parts EM of the plurality of anodes and exposing a part of the auxiliary electrode, a bank protection pattern PP provided on the side surface of the bank surrounding the bank hole LOP and on the bank 150 around the bank hole LOP, an interlayer 220 provided on the light emitting parts EM and the bank 150, and a cathode 230 connected to the auxiliary electrode 205 within the bank hole LOP.

The anode 210, the interlayer 220, and the cathode 230 laminated stacked in each light emitting part EM constitute a light emitting element ED.

The anode 210 is provided for each light emitting part EM and connected to a thin film transistor TFT therebelow to receive a driving signal and operate separately for each light emitting part EM. The cathode 230 is continuously formed across the light emitting parts EM. The cathode 230 of the light emitting display device of the present disclosure is connected to the power supply (16 in FIG. 1) in the non-display area NA and is connected to a common power line or an auxiliary power line provided in the non-display area NA to receive an electrical signal. In addition, the cathode 230 may be connected to the auxiliary electrode 205 provided in a region overlapping with the bank 150 to receive a common voltage or the low-potential voltage in the display area AA. Therefore, it is possible to prevent luminance non-uniformity due to different distances from the power supply in a large light emitting display device and uniformly adjust luminance in the entire display area AA.

A non-overlapping portion of the bank 150 and the anode 210 is defined as a light emitting part EM. In addition, the bank 150 has a bank hole LOP therein to expose the auxiliary electrode 205, and the cathode 230 is connected to the auxiliary electrode 205 within the bank hole LOP. Here, the side surface BLS of the bank 150 surrounding the bank hole LOP and the top surface BTS of the bank 150 are not directly connected to the cathode 230, and the protection pattern PP is provided thereon, and thus the bank 150 may be prevented from being affected by outgassing due to exposure of the bank 150.

The bank 150 is made of an organic insulating material and may have a predetermined height. The bank 150 may have a height of approximately 1 μm to 5 μm, and is positioned between the light emitting parts EM, and the regions of the light emitting parts EM may be divided due to a height difference between the bank 150 and the light emitting parts EM.

The bank 150 may be made of, for example, at least one organic material such as polyimide, polyamide, or an acrylate resin. In the light emitting display device of the present disclosure, the bank 150 is made of an organic material, and the auxiliary electrode 205 overlapping with the bank 150 is exposed after the bank 150 and the interlayer OS are formed. Here, the bank protection pattern PP may be additionally formed on the side surface and/or top surface of the bank 150 that are also exposed when the auxiliary electrode 205 is exposed, to prevent outgassing in which carbon-based components are emitted according to aging after bank exposure from affecting the interlayer OS.

The interlayer 220 positioned between the anode 210 and the cathode 230 of the light emitting element ED has a stack structure including at least one emission layer and at least one common layer. For example, the stack constituting the interlayer 220 may include a hole injection layer, a hole transport layer, an emission layer, an electron transport layer, and an electron injection layer. As another example, the interlayer 220 may include a plurality of stacks and may include a charge generation layer between the stacks. Further, each stack may include a hole transport layer, an emission layer, and an electron transport layer.

The interlayer 220 may include emission layers emitting lights of different colors for respective light emitting parts EM. Alternatively, emission layers emitting lights of different colors may be included in the interlayer 220 in an overlapping manner. When the interlayer 220 includes emission layers emitting lights of different colors, the light emitting display device may further include color filters on the emitting side to express colors.

In the light emitting display device of the present disclosure, the interlayer 220 does not directly contact the bank 150 by being surrounded by the bank protection pattern PP in the region where the interlayer 220 overlaps with the bank 150, and thus the interlayer 220 may be prevented from being affected by outgassing from the side surface of the bank 150 exposed when the bank hole LOP is formed in the bank 150 to connect the auxiliary electrode 205 and the cathode 230.

The bank protection pattern PP may include a first protection pattern 215 positioned on the top surface BTS of the bank 150, and a second protection pattern 225 formed on the bank side surface BLS surrounding the bank hole LOP and the top surface and the side surface of the interlayer 220 on the bank.

The first protection pattern 215 and the second protection pattern 225 may overlap with the top surface BTS of the bank 150 and may be positioned below and on the interlayer 220.

The bank protection pattern PP may include both the first protection pattern 215 and the second protection pattern 225 or may include any one thereof. Even when only one of the first protection pattern 215 and the second protection pattern 225 is provided, it is possible to protect the interlayer 220 and the cathode 230 from deformation of the bank 150 that occurs when the bank hole LOP is formed. It may be more effective that the bank protection pattern PP include the second protection pattern 225 provided on the sidewall of the bank hole LOP to protect the interlayer 220 from deformation of the bank 150.

The bank protection pattern PP is, for example, formed on the top surface BTS and the side surface BLS of the bank 150 to protect the interlayer 220 and the cathode 230, and may be made of an inorganic insulating material having protective properties against outgassing containing a carbon compound. For example, the bank protection pattern PP may be formed of a material such as silicon nitride (SiNx), silicon oxide (SiOx), silicon oxynitride (SiOxNy), and aluminum oxide (Al₂O₃). The first protection pattern 215 and the second protection pattern 225 of the bank protection pattern PP may be made of the same inorganic insulating material or different inorganic insulating materials. In addition, it is desirable to form the bank protection pattern PP of an inorganic insulating material to prevent electrical influence at a portion of contact with the cathode 230.

Meanwhile, since the light emitting display device may be applied to applications that may be used in extreme or extremely cold outdoor environments, a UV shielding material may be included in the bank protection pattern PP to protect the inside of the light emitting display device against ultraviolet rays in outdoor environments. For example, the bank protection pattern PP may be formed of an oxide layer or a nitride layer containing at least one of zinc, silicon, titanium, and tantalum. The bank protection pattern PP including such a UV shielding component surrounds the interlayer 220 in the region where it overlaps with the bank 150 and thus may prevent the bank 150 from being deformed by the ultraviolet rays and prevent outgassing, stabilizing the interlayer 220.

The first protection pattern 215 and the second protection pattern 225 formed through different processes may meet each other at a portion between the bank side surface BLS surrounding the bank hole LOP and the top surface BTS of the bank.

In the light emitting display device of the present disclosure, the auxiliary electrode 205 may be positioned on the same layer as the anode 210. Further, the auxiliary electrode 205 may be made of the same material as the anode 210. Therefore, the auxiliary electrode 205 and the anode 210 may be formed through the same process, and thus there is no need to additionally use a separate metal for the connection structure of the cathode 230 in the display area AA, and an additional material or mask is not added to form the auxiliary electrode 205. Accordingly, it is not necessary to adjust the areas occupied by the light emission parts for formation of the auxiliary electrode 205 positioned in the non-emitting part in the light emitting display device of the present disclosure, and thus it is possible to improve the luminance of the entire light emission display device while maintaining an aperture ratio.

A capping layer may be further provided on the cathode 230 of the light emitting element ED to protect the light emitting element ED and increase light emission effects. In addition, an encapsulation layer 300 may be further provided on the light emitting element ED to protect the light emitting element ED from external air and moisture.

The thin film transistor TFT connected to the anode 210 will be described.

The thin film transistor TFT may include a semiconductor layer 103, a gate electrode 104 overlapping with a channel of the semiconductor layer 103 having a gate insulating layer 107 interposed therebetween, and a source electrode 105 and a drain electrode 106 connected to both sides of the semiconductor layer 103. The drain electrode 106 of the thin film transistor TFT may be connected to the anode 210 of the light emitting element ED through a first contact hole CT1 penetrating a planarization layer 108 and a passivation layer 109.

In some cases, the source electrode 105 of the thin film transistor TFT may be connected to the anode 210.

In addition, a light blocking layer 101 may be further provided under the semiconductor layer 103 to prevent the semiconductor layer 103 from being affected by light introduced into the substrate 100 from the lower side of the substrate 100.

A buffer layer 102 is provided between the light blocking layer 101 and the semiconductor layer 103. The buffer layer 102 may be formed on the entire area of the substrate 100 to cover the light blocking layer 101.

The semiconductor layer 103 may be formed of at least one of an oxide semiconductor, amorphous silicon, and crystalline silicon.

The illustrated thin film transistor TFT is an example and has a coplanar structure in which the gate electrode 104, the source electrode 105, and the drain electrode 106 are on the same plane, but the present disclosure is not limited thereto. For example, the thin film transistor may have a bottom gate structure in which the gate electrode is positioned below the semiconductor layer, or a top gate structure in which the gate electrode is positioned above the semiconductor layer. Further, the gate electrode, the source electrode, and the drain electrode of the thin film transistor may be located on different planes, that is, on different layers.

In some cases, the semiconductor layer 103 may further include a conductive layer at portions connected to the source electrode 105 and the drain electrode 106.

The planarization layer 108 is provided for planarization and may be, for example, made of at least one organic material such as photo acryl, polyimide, benzocyclobutene resin, or acrylate resin. The planarization layer 108 may be made of at least one of the materials.

The anode 210 and the auxiliary electrode 205 may be formed in contact with each other on the flat top surface of the planarization layer 108.

The anode 210 (pixel electrode or first electrode) and the auxiliary electrode 205 may be formed of a metal, an alloy thereof, or a combination of a metal and an oxide metal. For example, the anode 210 and the auxiliary electrode 205 may be formed in a multilayer structure including a transparent conductive layer and an opaque conductive layer having high reflective efficiency in the case of a top emission type. The transparent conductive layer of the anode 210 and the auxiliary electrode 205 may be made of a material having a relatively large work function value such as indium tin oxide (ITO) and indium zinc oxide (IZO), and the opaque conductive layer may be formed of a single layer or multiple layers of one of silver (Ag), aluminum (Al), copper (Cu), molybdenum (Mo), titanium (Ti), nickel (Ni), chromium (Cr), and tungsten (W) or an alloy thereof. For example, the anode 210 may be formed in a structure in which a transparent conductive layer, an opaque conductive layer, and a transparent conductive layer are sequentially laminated, or in a structure in which a transparent conductive layer and an opaque conductive layer are sequentially laminated. In some cases, when the anode 210 is form of multiple layers, the auxiliary electrode 205 may be formed of only a part of the multiple layers. The auxiliary electrode 205 is directly connected to the cathode 230 and may be formed of only an opaque conductive layer having high conductivity or a reflective electrode.

The cathode 230 may be made of a transparent conductive material such as indium-tin-oxide (ITO) or indium-zinc-oxide (IZO), or may be made of silver (Ag), aluminum (Al), magnesium (Mg), calcium (Ca), ytterbium (Yb), or an alloy including at least one thereof and may be formed to be sufficiently thin to allow light to pass through.

As illustrated in FIG. 2, the auxiliary electrode 205 may be connected to a common power line VSSL formed on the same layer as at least one electrode of the thin film transistor TFT through a second contact hole CT2 penetrating the planarization layer 108 and the passivation layer 109.

The common power line VSSL extends to the non-display area NA of the substrate 100 and is connected to the power supply to receive the low-potential voltage.

The structure from the substrate 100 to the planarization layer 108 of the light emitting element ED includes the thin film transistor TFT and thus is referred to as a thin film transistor array substrate 800. Although FIG. 2 shows only a single thin film transistor TFT for each light emitting element ED, the light emitting display device of the present disclosure is not limited thereto and may include a plurality of thin film transistors and at least one capacitor for each sub-pixel for circuit operation. The thin film transistor array substrate 800 includes a plurality of thin film transistors and a capacitor provided for each sub-pixel.

The buffer layer 102, the gate insulating layer 107, and the passivation layer 109 between the light blocking layer 101 and the semiconductor layer 103 in the thin film transistor array substrate 800 may be formed of inorganic insulating layers. Examples of inorganic insulating layers may include a silicon oxide layer, a silicon nitride layer, a silicon oxynitride layer, and a metal oxide layer.

The planarization layer 108 is made of an organic insulating material and may be made of, for example, at least one of photo acryl, polyimide, benzocyclobutene resin, and acrylate resin.

The light emitting element ED may be provided on the thin film transistor array substrate 800.

In the light emitting display device of the present disclosure, the bank 150 for defining the light emitting part EM of the anode 210 and the bank hole LOP for exposing a part of the auxiliary electrode 205 overlapping with the bank 150 may be simultaneously formed or formed through different processes. Structures of the bank 150 and the bank hole LOP formed through different processes will be described later along with a method of forming the same.

The first protection pattern 215 of the bank protection pattern PP is provided on the top surface BTS of the bank before formation of the bank hole LOP and is in contact with the top surface BTS of the bank. The second protection pattern 225 of the bank protection pattern PP is formed after a portion of the bank 150 corresponding to the bank hole LOP is removed after formation of the interlayer 220. The second protection pattern 225 is formed in contact with the top and side surfaces of the interlayer 220 and the side surface BLS of the bank 150 surrounding the bank hole LOP.

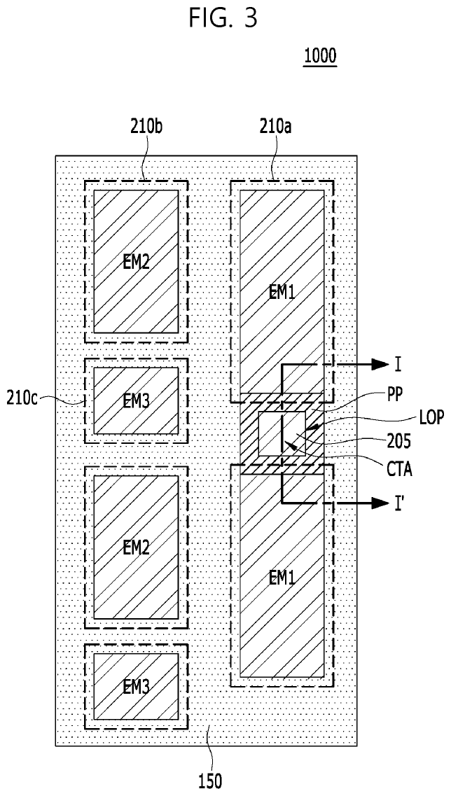

FIG. 3 is a plan view illustrating the light emitting display device according to a first aspect of the present disclosure.

As illustrated in FIG. 3, the light emitting display device 1000 according to the first aspect of the present disclosure may include first to third light emitting parts EM1, EM2, and EM3 emitting lights of different colors, and the bank protection pattern PP between light emitting parts EM1 emitting light of the same color. The light emitting parts EM1, EM2, and EM3 may be light emitting parts emitting blue light, green light, and red light, for example. However, the present disclosure is not limited thereto, the first to third light emitting parts EM1, EM2, and EM3 may emit lights of different colors as long as they may emit white light according to a combination. As another example, the first to third light emitting parts EM1, EM2, and EM3 may be cyan, magenta, and yellow light emitting parts.

Further, the light emitting parts EM1, EM2, and EM3 may have the same size or different sizes. In the example illustrated in FIG. 3, the first light emitting part EM1 is the largest, the second and third light emitting parts EM2 and EM3 are smaller than the first light emitting part EM1, and the second and third light emitting parts EM2 and EM3 are disposed adjacent to a single first light emitting part EM1. As a color light emitting part having low light emission efficiency in the same area, the first light emitting part EM1 may be formed to occupy a large area in the light emitting display device 1000 to compensate for relative efficiency differences between the first light emitting part EM1 and the second and third light emitting parts EM2 and EM3.

First to third anodes 210a, 210b, and 210c may be provided in the first to third light emitting parts EM1, EM2, and EM3. The first to third anodes 210a, 210b, and 210c extend from the entire the light emitting parts EM1, EM2, and EM3 and the edges of the light emitting parts to partially overlap with the bank 150 of the non-light emitting part. Here, the first to third anodes 210a, 210b, and 210c are spaced apart from each other and independently driven by being connected to the thin film transistors TFT provided therebelow, described in FIG. 2.

FIG. 3 shows a case in which, in the light emitting display device 1000 according to the first aspect of the present disclosure, a connection area CTA between the auxiliary electrode 205 and the cathode 230 is provided between the light emitting parts EM1 having the same color. This is an example, the light emitting display device of the present disclosure is not limited thereto, and the connection area CTA may be provided between light emitting parts having different colors. In addition, the auxiliary electrode 205 and the cathode 230 may be connected between the second light emitting parts EM2 and/or between the third light emitting parts EM3 as well as between the first light emitting parts EM1.

The bank hole LOP exposes a portion of the auxiliary electrode 205, and the bank protection pattern PP is disposed on the side and top surface of the bank 150 around the bank hole LOP to prevent outgassing due to bank exposure from affecting the interlayer 220 and the cathode 230 during formation of the bank hole LOP.

As illustrated in FIGS. 2 and 3, the edge of the bank protection pattern PP may contact the anodes 210 (210a, 210b, and 210c) positioned at the edges of the light emitting parts EM1, EM2, and EM3 to completely protect the bank 150 around the bank hole LOP.

Portions of adjacent first light emitting parts EM1 emitting the same color of light and an area along line I-I′ passing between the portions in FIG. 3 may correspond to the area shown in FIG. 2.

However, the light emitting display device of the present disclosure is not limited thereto. The bank hole and the bank protection pattern around the bank hole may also be formed between light emitting parts emitting lights of different colors, which will be described below.

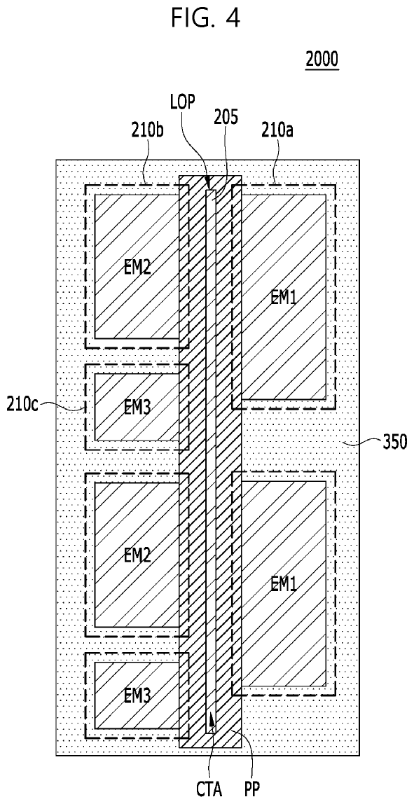

FIG. 4 is a plan view illustrating a light emitting display device according to a second aspect of the present disclosure.

As illustrated in FIG. 4, in the light emitting display device 2000 according to the second aspect of the present disclosure, the bank protection pattern PP is provided on the bank hole LOP and the top and side surfaces of the bank 150 around the bank hole LOP between the first light emitting part EM1 and the second light emitting part EM2 adjacent to each other and between the first light emitting part EM1 and the third light emitting part EM3 adjacent to each other.

As illustrated in FIG. 2, since the interlayer 220 is removed in the bank hole LOP, the interlayer 220 is disconnected between the first light emitting part EM1 and the second light emitting part EM2 and between the first light emitting part EM1 and the third light emitting part EM3 in the light emitting display device 2000 according to the second aspect of the present disclosure. Therefore, the interlayer 220 is disconnected due to provision of the common layer, and thus the common layer between the adjacent first light emitting part EM1 and second light emitting part EM2 is separated from the common layer between the adjacent first light emitting part EM1 and third light emitting part EM3. Accordingly, leakage current due to the common layer may be prevented.

For example, if the first light emitting part EM1 is a blue light emitting part, the second light emitting part EM2 is a green light emitting part, the third light emitting part EM3 is a red light emitting part, the first light emitting part EM1 has a high turn-on voltage, and the second and third light-emitting parts EM2 and EM3 have a low turn-on voltage, color leakage from the second and third light emitting parts EM2 and EM3 in an off state may occur in a state in which the first light emitting part EM1 is selectively turned on. Such color leakage may be noticeable due to the common layer having high mobility in the first to third light emitting parts EM1, EM2, and EM3. In the light emitting display device 2000 according to the second aspect of the present disclosure, the bank hole LOP in the banks 350 is positioned between the first light emitting part EM1 and the second light emitting part EM2 which emit lights of different colors and between the first light emitting part EM1 and the third light emitting part EM3 which emit lights of different colors, and the interlayer 220 corresponding to the bank hole LOP is removed when the bank 150 is selectively removed to form the bank hole LOP to eliminate the cause of leakage current flowing in the horizontal direction. Therefore, the light emitting display device 2000 according to the second aspect of the present disclosure may solve luminance non-uniformity in the display area AA due to connection between the auxiliary electrode 205 and the cathode 230 and prevent lateral leakage current between adjacent light emitting parts.

The light emitting display device 2000 according to the second aspect of the present disclosure may prevent leakage current between adjacent color light emitting parts because the interlayer between the adjacent color light emitting parts may be patterned.

Hereinafter, a method of manufacturing a light emitting display device according to the present disclosure will be described.

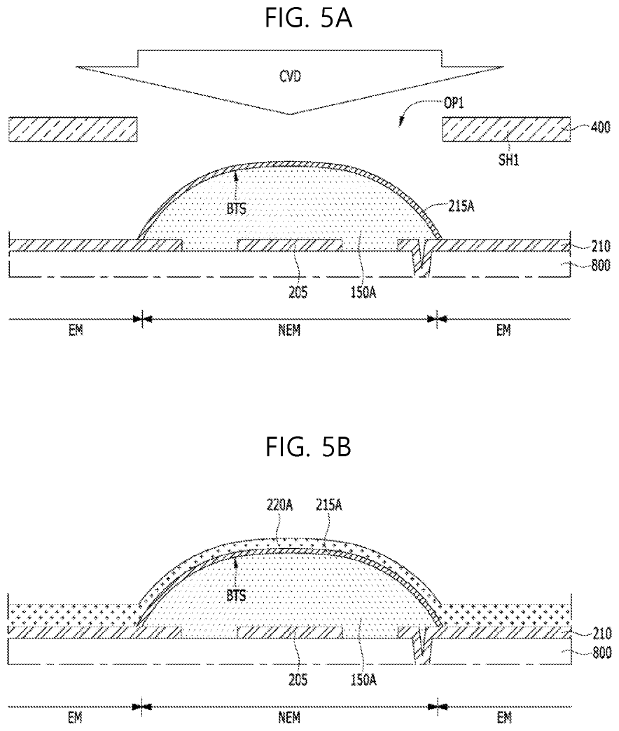

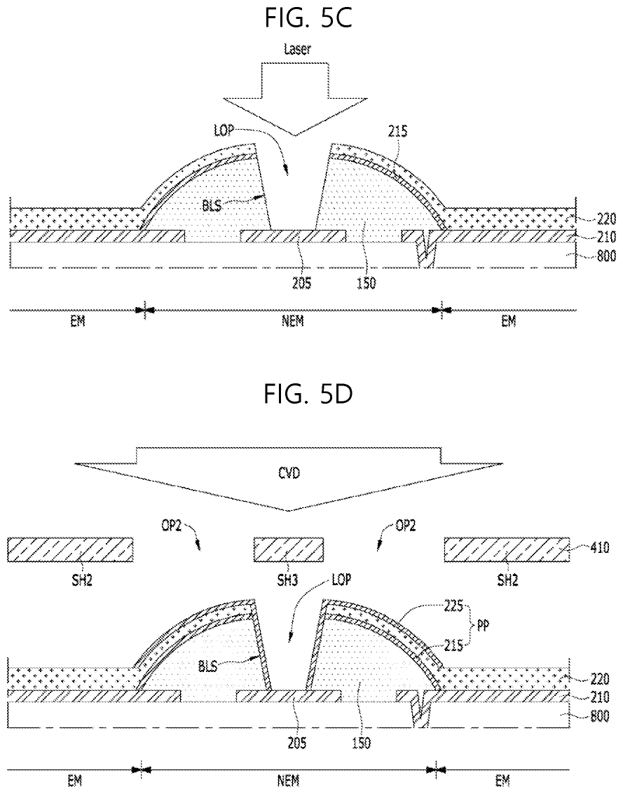

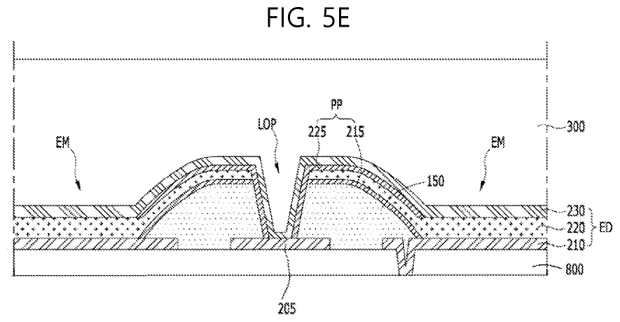

FIGS. 5A to 5E are cross-sectional views illustrating a process of a method of manufacturing the light emitting display device according to the present disclosure.

First, a thin film transistor array substrate 800 including a thin film transistor TFT is formed on the substrate 100 described in FIG. 2.

The top surface of the thin film transistor array substrate 800 may be a planarization layer (108 in FIG. 2).

As illustrated in FIG. 5A, a plurality of anodes 210 spaced apart from each other and an auxiliary electrode 205 disposed between adjacent anodes are formed on the thin film transistor array substrate 800. The anodes 210 and the auxiliary electrode 205 may be formed by patterning an opaque conductive layer having high reflective efficiency. Alternatively, if the anodes 210 and the auxiliary electrode 205 are formed in a multilayer structure, the anodes 210 and the auxiliary electrode 205 may be formed in a multilayer structure including a transparent conductive layer and an opaque conductive layer having high reflective efficiency. The transparent conductive layer of the anodes 210 and the auxiliary electrode 205 may be made of a material having a relatively large work function value such as indium tin oxide (ITO) or indium zinc oxide (IZO) and the opaque conductive layer may be formed of a single layer or multiple layers of one selected from the group consisting of silver (Ag), aluminum (Al), copper (Cu), molybdenum (Mo), titanium (Ti), nickel (Ni), chromium (Cr), and tungsten (W) or an alloy thereof. For example, the anode 210 may be formed in a structure in which a transparent conductive layer, an opaque conductive layer, and a transparent conductive layer are sequentially laminated, or in a structure in which a transparent conductive layer and an opaque conductive layer are sequentially laminated. In some cases, if the anodes 210 are formed of multiple layers, the auxiliary electrode 205 may be formed of only some of the multiple layers. The auxiliary electrode 205 is directly connected to the cathode 230, and may be made of only an opaque conductive layer having high conductivity or a reflective electrode.

Subsequently, a bank layer 150A covering the entire auxiliary electrode 205 and exposing light emitting parts EM of the anodes 210 while overlapping with the edges of the adjacent anodes 210 is formed.

A mask 400 having a first opening OP1 exposing the bank layer 150A and having light blocking parts SH1 corresponding to the light emitting parts of the anodes 210 is placed above the thin film transistor array substrate 800, and a protection pattern material is deposited on the top surface BTS of the bank layer 150A to form a first protection pattern layer 215A. In this case, the first protection pattern layer 215A covers the surface of the bank layer 150A and prevents the interlayer 220 which will be formed thereafter from directly contacting the bank layer 150A, thereby preventing the influence of outgassing due to exposure of the bank layer 150A during a process of selectively removing the bank layer 150A.

Subsequently, as illustrated in FIG. 5B, an interlayer material film 220A is formed on the light emitting parts EM and non-emitting parts NEM. The interlayer material film 220A contacts the light emitting parts EM of the anodes 210 and contacts the first protection pattern layer 215A in a region overlapping with the bank layer 150A.

The interlayer material film 220A includes at least one stack, and the stack includes at least one emission layer and at least one common layer. The common layer is formed using an open mask, and at least the common layer of the interlayer material film 220A is provided not only in the light emitting parts EM but also in the non-emitting parts NEM. The emission layer included in the interlayer material film 220A may also be provided in both the light emitting parts EM and the non-emitting parts NEM according to circumstances.

Subsequently, as illustrated in FIG. 5C, the interlayer material film 220A, the first protection pattern layer 215A, and the bank layer 150A are removed to expose a portion of the auxiliary electrode 205, thereby forming a bank 150 having a bank hole LOP. This removal process may be performed by, for example, laser irradiation.

After the bank hole LOP is formed in the bank 150, the side surface BLS of the bank surrounding the bank hole LOP may be exposed. In addition, a portion of the interlayer material film corresponding to the bank hole LOP is removed to form an interlayer 220 having a discontinuity between adjacent light emitting parts.

Subsequently, as illustrated in FIG. 5D, a second mask 410 having first light blocking parts SH2 corresponding to the light emitting parts EM, a second light blocking part SH3 corresponding to the bank hole LOP, and a second opening OP2 corresponding to the exposed bank 150 is placed above the thin film transistor array substrate 800, and then a protection pattern material is deposited thereon through the second opening OP2 to form a second protection pattern 225.

Here, the second protection pattern 225 is formed on the upper surface of the interlayer 220 overlapping with the bank 150 and on the side surface of the interlayer 220 and the bank side surface BLS surrounding the bank hole LOP.

Subsequently, as illustrated in FIG. 5E, a cathode 230 (a second electrode or a common electrode) is formed on the interlayer 220.

The cathode 230 is formed using an open mask and positioned in contact with the interlayer 220 on the light emitting parts EM, and directly contacts an auxiliary electrode 205 in the bank hole LOP.

In addition, the cathode 230 does not directly contact the bank 150 by the second protection pattern 225 on the bank side surface BLS and bank top surface BTS around the bank hole LOP, and even if outgassing occurs due to deformation of the bank caused by laser irradiation in the process of FIG. 5C, the second protection pattern 225 blocks the outgassing to protect the interlayer 220 and the protection pattern 225.

The anode 210, the interlayer 22, and the cathode 230 laminated in each light emitting part EM constitute a light emitting element ED.

In addition, an encapsulation layer 300 is provided on the light emitting part EM for protection.

The encapsulation layer 300 may be formed by alternately forming an inorganic encapsulation film and an organic encapsulation film, for example.

In the light emitting display device of the present disclosure, an auxiliary electrode overlapping with a bank is provided, a part of the auxiliary electrode is exposed through a process of removing components on the auxiliary electrode before formation of a cathode, and the cathode and the auxiliary electrode are directly connected. Accordingly, by providing a portion where the cathode and the auxiliary electrode are connected in an active area (display area), voltage uniformity of the cathode may be improved and luminance reduction may be prevented.

A light emitting display device according to one or more aspects of the present disclosure may comprise a plurality of anodes spaced apart from each other on a substrate, an auxiliary electrode between adjacent anodes among the plurality of anodes, a bank exposing light emitting parts of the plurality of anodes and having a bank hole exposing a part of the auxiliary electrode, a bank protection pattern on a bank side surface surrounding the bank hole and on the bank around the bank hole, an interlayer on the light emitting parts and the bank and a cathode connected to the auxiliary electrode within the bank hole.

In a light emitting display device according to one or more aspects of the present disclosure, the bank protection pattern may include a first protection pattern in contact with a top surface of the bank around the bank hole and a second protection pattern in contact with the interlayer on the bank and the bank side surface surrounding the bank hole.

In a light emitting display device according to one or more aspects of the present disclosure, the first protection pattern and the second protection pattern may meet each other at a region where the bank side surface surrounding the bank hole and the top surface of the bank meet.

In a light emitting display device according to one or more aspects of the present disclosure, the first protection pattern and the second protection pattern may overlap with the top surface of the bank and are positioned under and on the interlayer.

In a light emitting display device according to one or more aspects of the present disclosure, the bank protection pattern may comprise an inorganic insulating layer.

In a light emitting display device according to one or more aspects of the present disclosure, the bank protection pattern may comprise a UV-blocking component.

In a light emitting display device according to one or more aspects of the present disclosure, an edge of the interlayer on the auxiliary electrode may be positioned on the bank surrounding the bank hole.

In a light emitting display device according to one or more aspects of the present disclosure, the interlayer overlapping with the bank may be surrounded by the bank protection pattern.

In a light emitting display device according to one or more aspects of the present disclosure, the plurality of anodes and the auxiliary electrode may be disposed on the same layer.

In a light emitting display device according to one or more aspects of the present disclosure, the bank protection pattern may be interposed between the bank and the cathode at a portion where the cathode and the bank overlap with each other.

A method of manufacturing a light emitting display device according to one or more aspects of the present disclosure may comprise a first step of forming a plurality of anodes spaced apart from each other on a substrate, a second step of forming an auxiliary electrode between adjacent anodes among the plurality of anodes, a third step of forming a bank exposing light emitting parts of the plurality of anodes, a fourth step of forming a first protection pattern on the bank and a fifth step of forming an interlayer and a cathode overlapping with the first protection pattern.

In a method of manufacturing a light emitting display device according to one or more aspects of the present disclosure, the fifth step comprises forming a bank hole by removing the interlayer, the first protection pattern, and the bank to expose a portion of the auxiliary electrode after forming the interlayer, forming a second protection pattern on a side surface of the bank and a side surface of the interlayer surrounding the bank hole, and on the interlayer overlapping with the bank and forming the cathode on the interlayer, the cathode connected to the auxiliary electrode within the bank hole and overlapping with the second protection pattern on the bank.

The light emitting display device of the present disclosure has the following effects.

First, an auxiliary electrode overlapping with a bank is provided, a part of the auxiliary electrode is exposed by removing components on the auxiliary electrode before a cathode is formed, and the auxiliary electrode and the cathode are directly connected. Therefore, a connection portion of the cathode and the auxiliary electrode is provided in an active area (display area), to improve voltage uniformity of the cathode and prevent luminance reduction.

Second, outgassing due to exposure of the bank may be prevented by forming a bank protection pattern on the side and the upper surface of the bank surrounding a bank hole formed to expose the auxiliary electrode.

Third, the upper and side surfaces of the bank are covered by the bank protection pattern before an interlayer is formed, and thus the interlayer subsequently formed is prevented from being directly connected to the bank layer, to prevent deterioration of the bank due to exposure. Further, the contact area of the interlayer and the bank may be reduced to prevent the interlayer from being damaged due to bank outgassing.

Fourth, a transparent inorganic insulating layer used in the field of display devices may be used for the bank protection pattern, and thus a reliable light emitting display device may be manufactured without using additional materials. Accordingly, ESG (Environment/Social/Governance) effects may be obtained in terms of eco-friendliness, low power consumption, and process optimization.

Fifth, when a bank hole is provided between light emitting parts emitting lights of different colors, the interlayer is removed in the bank hole and the interlayer between adjacent color light emitting parts may be patterned in the process of forming the bank hole, and thus leakage current between adjacent light emitting parts may be prevented.

It will be apparent to those skilled in the art that various modifications and variations may be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A light emitting display device comprising:
a plurality of anodes spaced apart from each other on a substrate;
an auxiliary electrode disposed between adjacent anodes among the plurality of anodes;
a bank exposing light emitting parts of the plurality of anodes and having a bank hole exposing a part of the auxiliary electrode;
a bank protection pattern disposed on a bank side surface surrounding the bank hole and on the bank around the bank hole;
an interlayer disposed on the light emitting parts and the bank; and
a cathode connected to the auxiliary electrode within the bank hole.

2. The light emitting display device of claim 1, wherein the bank protection pattern includes:
a first protection pattern in contact with a top surface of the bank around the bank hole; and
a second protection pattern in contact with the interlayer on the bank and the bank side surface surrounding the bank hole.

3. The light emitting display device of claim 2, wherein the first protection pattern and the second protection pattern meet with each other at a region where the bank side surface surrounding the bank hole and the top surface of the bank meet.

4. The light emitting display device of claim 2, wherein the first protection pattern and the second protection pattern overlap with the top surface of the bank and are positioned under and on the interlayer.

5. The light emitting display device of claim 1, wherein the bank protection pattern comprises an inorganic insulating layer.

6. The light emitting display device of claim 1, wherein the bank protection pattern comprises a UV-blocking component.

7. The light emitting display device of claim 1, wherein an edge of the interlayer on the auxiliary electrode is positioned on the bank surrounding the bank hole.

8. The light emitting display device of claim 1, wherein the interlayer overlapping with the bank is surrounded by the bank protection pattern.

9. The light emitting display device of claim 1, wherein the plurality of anodes and the auxiliary electrode are disposed on the same layer.

10. The light emitting display device of claim 1, wherein the bank protection pattern is interposed between the bank and the cathode at a portion where the cathode and the bank overlap with each other.

11. A method of manufacturing a light emitting display device, comprising;
forming a plurality of anodes spaced apart from each other on a substrate;
forming an auxiliary electrode between adjacent anodes among the plurality of anodes;
forming a bank exposing light emitting parts of the plurality of anodes;
forming a first protection pattern on the bank; and
forming an interlayer and a cathode overlapping with the first protection pattern.

12. The method of claim 11, wherein the forming the interlayer and a cathode comprises:
forming a bank hole by removing the interlayer, the first protection pattern, and the bank to expose a portion of the auxiliary electrode after forming the interlayer;
forming a second protection pattern on a side surface of the bank and a side surface of the interlayer surrounding the bank hole, and on the interlayer overlapping with the bank; and
forming the cathode on the interlayer, the cathode connected to the auxiliary electrode within the bank hole and overlapping with the second protection pattern on the bank.
